(19) United States
(12) Patent Application Publication
(10) Pub. No.: US 2026/0180541 A1
(43) Pub. Date: Jun. 25, 2026

(54) PLASMA PROCESSING APPARATUS AND IMPEDANCE MATCHING METHOD

(71) Applicant: Tokyo Electron Limited, Tokyo (JP)

(72) Inventor: Shintaro YAWATA, Kurokawa-gun (JP)

(21) Appl. No.: 19/541,792

(22) Filed: Feb. 17, 2026

Related U.S. Application Data
(63) Continuation of application No. PCT/JP2024/020643, filed on Jun. 6, 2024.

(30) Foreign Application Priority Data
Aug. 28, 2023 (JP) 2023-138111

(51) Int. Cl. H03H 7/38; H01J 37/32

(52) U.S. Cl. CPC H03H 7/38; H01J 37/32082; H01J 37/32091; H01J 37/32183; H01J 2237/334

(57) ABSTRACT

A plasma processing apparatus includes a chamber, a substrate support in the chamber and including a lower electrode, an upper electrode above the substrate support, a source radio-frequency generator that provides a source radio-frequency signal to the upper or lower electrode to generate a plasma in the chamber, an impedance matcher electrically coupled to a transmission line between the source radio-frequency generator and the upper or lower electrode and including a first low-speed matching circuit and a first high-speed matching circuit coupled in parallel, a bias generator that provides a bias signal to the lower electrode, and a controller that causes the first low-speed matching circuit to perform a low-speed matching operation on the source radio-frequency signal in a first period and causes the first high-speed matching circuit to perform a high-speed matching operation on the source radio-frequency signal in a second period following the first period.

This application is a bypass continuation application of international application No. PCT/JP2024/020643 having an international filing date of June 6, 2024, and designating the United States, the international application being based upon and claiming the benefit of priority from Japanese Patent Application No. 2023-138111, filed on August 28, 2023, the entire contents of which are incorporated herein by reference.

### BACKGROUND

### Field of the Invention

Exemplary embodiments of the present disclosure relate to a plasma processing apparatus and an impedance matching method.

### Description of Related Art

JP2006-134606 describes a matcher including a mechanical-controlled variable capacitor. JP2012-142285 describes a matcher including an electronic-controlled variable capacitor.

### SUMMARY

A plasma processing apparatus according to one exemplary embodiment of the present disclosure includes a chamber, a substrate support, an upper electrode, a source radio-frequency generator, an impedance matcher, a bias generator, and a controller. The substrate support is located in the chamber and includes a lower electrode. The upper electrode is located above the substrate support. The source radio-frequency generator provides a source radio-frequency signal to the upper electrode or the lower electrode to generate a plasma in the chamber. The impedance matcher is electrically coupled to a transmission line between the source radio-frequency generator and the upper electrode or between the source radio-frequency generator and the lower electrode. The impedance matcher includes a first low-speed matching circuit and a first high-speed matching circuit coupled in parallel with each other. The bias generator provides a bias signal to the lower electrode. The controller causes the first low-speed matching circuit to perform a low-speed matching operation on the source radio-frequency signal in a first period and causes the first high-speed matching circuit to perform a high-speed matching operation on the source radio-frequency signal in a second period following the first period.

### BRIEF DESCRIPTION OF DRAWINGS

FIG. 1 is a diagram of a plasma processing system, illustrating an example structure.

FIG. 2 is a diagram of a capacitively coupled plasma processing apparatus, illustrating an example structure.

FIG. 3 is a diagram of an example of coupling between a power supply 30 and a chamber 10.

FIG. 4 is a diagram of an example electronic variable capacitor.

FIG. 5 is a flowchart of an example matching method.

FIG. 6 is an example timing chart for the matching method.

FIG. 7A is an example timing chart with a high-speed matching operation not performed.

FIG. 7B is an example timing chart with the high-speed matching operation performed.

FIG. 8A is a diagram of an example of coupling in a modification of the structure shown in FIG. 3.

FIG. 8B is a diagram of an example of coupling in a modification of the structure shown in FIG. 3.

FIG. 8C is a diagram of an example of coupling in a modification of the structure shown in FIG. 3.

### DETAILED DESCRIPTION

One or more embodiments of the present disclosure will be described below.

A plasma processing apparatus according to one exemplary embodiment of the present disclosure includes a chamber, a substrate support, an upper electrode, a source radio-frequency generator, an impedance matcher, a bias generator, and a controller. The substrate support is located in the chamber and includes a lower electrode. The upper electrode is located above the substrate support. The source radio-frequency generator provides a source radio-frequency signal to the upper electrode or the lower electrode to generate a plasma in the chamber. The impedance matcher is electrically coupled to a transmission line between the source radio-frequency generator and the upper electrode or between the source radio-frequency generator and the lower electrode. The impedance matcher includes a first low-speed matching circuit and a first high-speed matching circuit coupled in parallel with each other. The bias generator provides a bias signal to the lower electrode. The controller causes the first low-speed matching circuit to perform a low-speed matching operation on the source radio-frequency signal in a first period and causes the first high-speed matching circuit to perform a high-speed matching operation on the source radio-frequency signal in a second period following the first period.

In one exemplary embodiment, the first low-speed matching circuit includes a first mechanical variable capacitor. The first high-speed matching circuit includes a first electronic variable capacitor. The first electronic variable capacitor includes a plurality of first capacitor elements and a plurality of first switching elements electronically coupled to the plurality of respective first capacitor elements.

In one exemplary embodiment, the first mechanical variable capacitor has a maximum capacitance greater than or equal to ten times a maximum capacitance of the first electronic variable capacitor.

In one exemplary embodiment, the first low-speed matching circuit performs the low-speed matching operation every about ten to several hundred milliseconds. The first high-speed matching circuit performs the high-speed matching operation every about several ten nanoseconds to several microseconds.

In one exemplary embodiment, the first period is a period from when plasma generation is started in the chamber to when the low-speed matching operation stabilizes.

In one exemplary embodiment, the first low-speed matching circuit and the first high-speed matching circuit are located between the transmission line and a ground potential.

In one exemplary embodiment, the impedance matcher includes a second low-speed matching circuit and a second high-speed matching circuit coupled in parallel with each other. The second low-speed matching circuit and the second high-speed matching circuit are located on the transmission line.

In one exemplary embodiment, the first low-speed matching circuit includes a first mechanical variable capacitor. The first high-speed matching circuit includes a first electronic variable capacitor. The first electronic variable capacitor includes a plurality of first capacitor elements and a plurality of first switching elements electronically coupled to the plurality of respective first capacitor elements. The second low-speed matching circuit includes a second mechanical variable capacitor. The second high-speed matching circuit includes a second electronic variable capacitor. The second electronic variable capacitor includes a plurality of second capacitor elements and a plurality of second switching elements electronically coupled to the plurality of respective second capacitor elements.

In one exemplary embodiment, the source radio-frequency generator changes a set value of a frequency of the source radio-frequency signal.

In one exemplary embodiment, the bias generator includes a bias radio-frequency generator that generates a bias radio-frequency signal.

In one exemplary embodiment, the bias generator includes a bias direct current generator that generates a bias direct current signal. The bias direct current signal has a sequence of voltage pulses.

A plasma processing apparatus according to one exemplary embodiment of the present disclosure includes a chamber, a substrate support, an antenna, a source radio-frequency generator, an impedance matcher, a bias generator, and a controller. The substrate support is located in the chamber and includes a lower electrode. The antenna is located above the chamber. The source radio-frequency generator provides a source radio-frequency signal to the antenna to generate a plasma in the chamber. The impedance matcher is electrically coupled to a transmission line between the source radio-frequency generator and the antenna. The impedance matcher includes a first low-speed matching circuit and a first high-speed matching circuit coupled in parallel with each other. The bias generator provides a bias signal to the lower electrode. The controller causes the first low-speed matching circuit to perform a low-speed matching operation on the source radio-frequency signal in a first period and causes the first high-speed matching circuit to perform a high-speed matching operation on the source radio-frequency signal in a second period following the first period.

In one exemplary embodiment, the first low-speed matching circuit includes a first mechanical variable capacitor. The first high-speed matching circuit includes a first electronic variable capacitor. The first electronic variable capacitor includes a plurality of first capacitor elements and a plurality of first switching elements electronically coupled to the plurality of respective first capacitor elements.

In one exemplary embodiment, the first low-speed matching circuit and the first high-speed matching circuit are located between the transmission line and a ground potential.

In one exemplary embodiment, the impedance matcher includes a second low-speed matching circuit and a second high-speed matching circuit coupled in parallel with each other. The second low-speed matching circuit and the second high-speed matching circuit are located on the transmission line.

In one exemplary embodiment, the first low-speed matching circuit includes a first mechanical variable capacitor. The first high-speed matching circuit includes a first electronic variable capacitor. The first electronic variable capacitor includes a plurality of first capacitor elements and a plurality of first switching elements electronically coupled to the plurality of respective first capacitor elements. The second low-speed matching circuit includes a second mechanical variable capacitor. The second high-speed matching circuit includes a second electronic variable capacitor. The second electronic variable capacitor includes a plurality of second capacitor elements and a plurality of second switching elements electronically coupled to the plurality of respective second capacitor elements.

In one exemplary embodiment, the source radio-frequency generator changes a set value of a frequency of the source radio-frequency signal.

An impedance matching method according to one exemplary embodiment of the present disclosure includes providing a radio-frequency signal to a load from a radio-frequency generator, causing a first low-speed matching circuit to perform a low-speed matching operation on the radio-frequency signal in a first period, and causing a first high-speed matching circuit to perform a high-speed matching operation on the radio-frequency signal in a second period following the first period. The first high-speed matching circuit is coupled in parallel with the first low-speed matching circuit.

In one exemplary embodiment, the first low-speed matching circuit includes a first mechanical variable capacitor. The first high-speed matching circuit includes a first electronic variable capacitor. The first electronic variable capacitor includes a plurality of first capacitor elements and a plurality of first switching elements electronically coupled to the plurality of respective first capacitor elements.

One or more embodiments of the present disclosure will now be described with reference to the drawings. In the drawings, like reference numerals denote the same or like components. Such components will not be described repeatedly. Unless otherwise specified, the positional relationships shown in the drawings are used to describe the vertical, lateral, and other positions. The drawings are not drawn to scale relative to the actual ratio of each component, and the actual ratio is not limited to the ratio in the drawings.

### Example Structure of Plasma Processing System

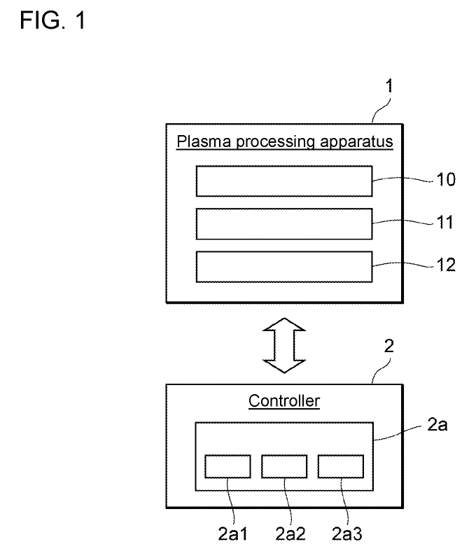

FIG. 1 is a diagram of a plasma processing system, illustrating an example structure. In one embodiment, the plasma processing system includes a plasma processing apparatus 1 and a controller 2. The plasma processing system is an example of a substrate processing system. The plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 also has at least one gas inlet for supplying at least one processing gas into the plasma processing space and at least one gas outlet for exhausting the gas from the plasma processing space. The gas inlet is connected to a gas supply 20 (described later). The gas outlet is connected to an exhaust system 40 (described later). The substrate support 11 is located in the plasma processing space and has a substrate support surface for supporting a substrate.

The plasma generator 12 generates a plasma from at least one processing gas supplied into the plasma processing space. The plasma generated in the plasma processing space may be, for example, a capacitively coupled plasma (CCP), an inductively coupled plasma (ICP), an electron cyclotron resonance (ECR) plasma, a helicon wave plasma (HWP), or a surface wave plasma (SWP). The plasma generator 12 may be one of various plasma generators including an alternating current (AC) plasma generator and a direct current (DC) plasma generator. In one embodiment, an AC signal (AC power) used in the AC plasma generator has a frequency in a range of 100 kHz to 10 GHz. Thus, the AC signal may be a radio-frequency (RF) signal or a microwave signal. In one embodiment, the RF signal has a frequency in a range of 100 kHz to 150 MHz.

The controller 2 processes computer-executable instructions that cause the plasma processing apparatus 1 to perform various steps described in one or more embodiments of the present disclosure. The controller 2 may control the components of the plasma processing apparatus 1 to perform the various steps described herein. In one embodiment, some or all of the components of the controller 2 may be included in the plasma processing apparatus 1. The controller 2 may include a processor 2a1, a storage 2a2, and a communication interface 2a3. The controller 2 is implemented by, for example, a computer 2a. The processor 2a1 may perform various control operations by loading programs from the storage 2a2 and executing the loaded programs. The programs may be prestored in the storage 2a2 or may be obtained through a medium as appropriate. The obtained programs are stored into the storage 2a2 to be loaded from the storage 2a2 and executed by the processor 2a1. The medium may be one of various storage media readable by the computer 2a or a communication line connected to the communication interface 2a3. The processor 2a1 may be a central processing unit (CPU). The storage 2a2 may include a random-access memory (RAM), a read-only memory (ROM), a hard disk drive (HDD), a solid-state drive (SSD), or a combination of these. The communication interface 2a3 may communicate with the plasma processing apparatus 1 through a communication line such as a local area network (LAN).

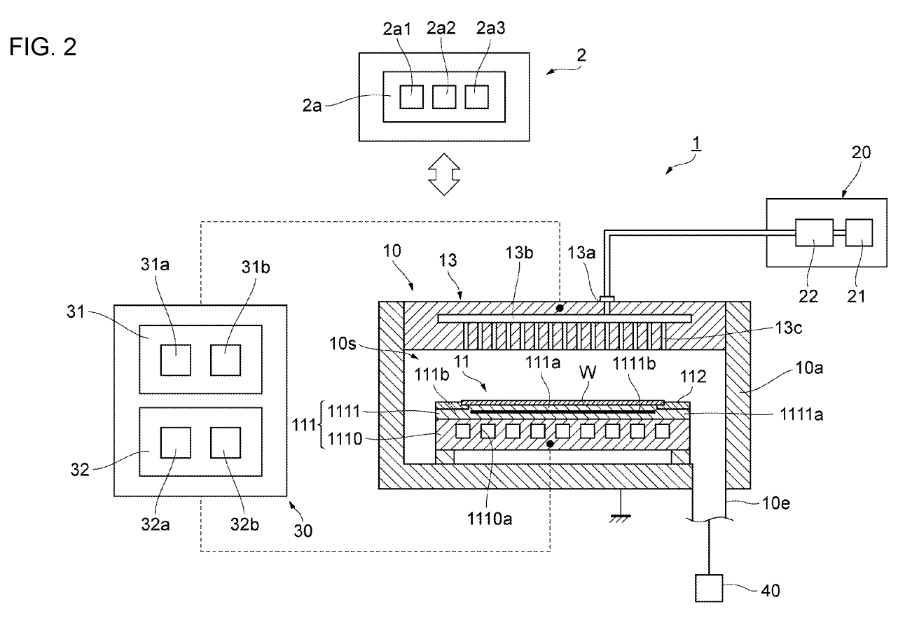

An example structure of a capacitively coupled plasma processing apparatus as an example of the plasma processing apparatus 1 will now be described. FIG. 2 is a diagram of the capacitively coupled plasma processing apparatus, illustrating an example structure.

The capacitively coupled plasma processing apparatus 1 includes the plasma processing chamber 10, the gas supply 20, a power supply 30, and the exhaust system 40. The plasma processing apparatus 1 further includes the substrate support 11 and a gas guide unit. The gas guide unit allows at least one processing gas to be introduced into the plasma processing chamber 10. The gas guide unit includes a showerhead 13. The substrate support 11 is located in the plasma processing chamber 10. The showerhead 13 is located above the substrate support 11. In one embodiment, the showerhead 13 defines at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 includes a central portion 111a for supporting a substrate W and an annular portion 111b for supporting the ring assembly 112. A wafer is an example of the substrate W. The annular portion 111b of the body 111 surrounds the central portion 111a of the body 111 as viewed in plan. The substrate W is placeable on the central portion 111a of the body 111. The ring assembly 112 is located on the annular portion 111b of the body 111 to surround the substrate W on the central portion 111a of the body 111. Thus, the central portion 111a is also referred to as a substrate support surface for supporting the substrate W. The annular portion 111b is also referred to as a ring support surface for supporting the ring assembly 112.

In one embodiment, the body 111 includes a base 1110 and an electrostatic chuck (ESC) 1111. The base 1110 includes a conductive member. The conductive member in the base 1110 may function as a lower electrode. The ESC 1111 is located on the base 1110. The ESC 1111 includes a ceramic member 1111a and an electrostatic electrode 1111b located inside the ceramic member 1111a. The ceramic member 1111a includes the central portion 111a. In one embodiment, the ceramic member 1111a also includes the annular portion 111b. The annular portion 111b may be included in another member surrounding the ESC 1111, such as an annular ESC or an annular insulating member. In this case, the ring assembly 112 may be located on the annular ESC or the annular insulating member, or may be located on both the ESC 1111 and the annular insulating member. At least one RF/DC electrode coupled to an RF power supply 31 or a DC power supply 32, or both (described later) may be located inside the ceramic member 1111a. In this case, the RF/DC electrode functions as a lower electrode. When a bias RF signal or a DC signal, or both (described later) are provided to at least one RF/DC electrode, the RF/DC electrode is also referred to as a bias electrode. The conductive member in the base 1110 and at least one RF/DC electrode may function as multiple lower electrodes. The electrostatic electrode 1111b may also function as a lower electrode. The substrate support 11 thus includes at least one lower electrode.

The ring assembly 112 includes one or more annular members. In one embodiment, the one or more annular members include one or more edge rings and at least one cover ring. The edge rings are formed from a conductive material or an insulating material. The cover ring is formed from an insulating material.

The substrate support 11 may include a temperature controller that adjusts the temperature of at least one of the ESC 1111, the ring assembly 112, or the substrate to a target temperature. The temperature controller may include a heater, a heat transfer medium, a channel 1110a, or a combination of these. The channel 1110a carries a heat transfer fluid such as brine or a gas. In one embodiment, the channel 1110a is defined inside the base 1110, and one or more heaters are located inside the ceramic member 1111a in the ESC 1111. The substrate support 11 may include a heat transfer gas supply to supply a heat transfer gas into a space between the back surface of the substrate W and the central portion 111a.

The showerhead 13 introduces at least one processing gas from the gas supply 20 into the plasma processing space 10s. The showerhead 13 includes at least one gas inlet 13a, at least one gas-diffusion compartment 13b, and multiple gas guides 13c. The processing gas supplied to the gas inlet 13a passes through the gas-diffusion compartment 13b and is introduced into the plasma processing space 10s through the gas guides 13c. The showerhead 13 further includes at least one upper electrode. In addition to the showerhead 13, the gas guide unit may include one or more side gas injectors (SGIs) installed in one or more openings in the sidewall 10a.

The gas supply 20 may include at least one gas source 21 and at least one flow controller 22. In one embodiment, the gas supply 20 supplies at least one processing gas from each gas source 21 to the showerhead 13 through the corresponding flow controller 22. The flow controller 22 may be, for example, a mass flow controller or a pressure-based flow controller. The gas supply 20 may further include at least one flow rate modulator that causes at least one processing gas to be supplied at a modulated flow rate or in a pulsed manner.

The power supply 30 includes the RF power supply 31 coupled to the plasma processing chamber 10 through at least one impedance matching circuit. The RF power supply 31 provides at least one RF signal (RF power) to at least one lower electrode or at least one upper electrode, or both. This generates a plasma from at least one processing gas supplied into the plasma processing space 10s. The RF power supply 31 may thus function as at least a part of the plasma generator 12. A bias RF signal is provided to at least one lower electrode to generate a bias potential in the substrate W, thus drawing ion components in the generated plasma toward the substrate W.

In one embodiment, the RF power supply 31 includes a first RF generator 31a and a second RF generator 31b. The first RF generator 31a is coupled to at least one lower electrode or at least one upper electrode, or both through at least one impedance matching circuit to generate a source RF signal (source RF power) for plasma generation. In one embodiment, the source RF signal has a frequency in a range of 10 to 150 MHz. In one embodiment, the first RF generator 31a may generate multiple source RF signals with different frequencies. One or more generated source RF signals are provided to at least one lower electrode or at least one upper electrode, or both.

The second RF generator 31b is coupled to at least one lower electrode through at least one impedance matching circuit to generate a bias RF signal (bias RF power). The frequency of the bias RF signal may be the same as or different from the frequency of the source RF signal. In one embodiment, the bias RF signal has a lower frequency than the source RF signal. In one embodiment, the bias RF signal has a frequency in a range of 100 kHz to 60 MHz. In one embodiment, the second RF generator 31b may generate multiple bias RF signals with different frequencies. One or more generated bias RF signals are provided to at least one lower electrode. In various embodiments, at least one of the source RF signal or the bias RF signal may be pulsed.

The power supply 30 may include the DC power supply 32 coupled to the plasma processing chamber 10. The DC power supply 32 includes a first DC generator 32a and a second DC generator 32b. In one embodiment, the first DC generator 32a is coupled to at least one lower electrode to generate a first DC signal. The generated first DC signal is applied to at least one lower electrode. In one embodiment, the second DC generator 32b is coupled to at least one upper electrode to generate a second DC signal. The generated second DC signal is applied to at least one upper electrode.

In various embodiments, the first DC signal and the second DC signal may be pulsed. In this case, the sequence of voltage pulses is applied to at least one lower electrode or at least one upper electrode, or both. The voltage pulses may have rectangular, trapezoidal, or triangular pulse waveforms, or a combination of these. In one embodiment, a waveform generator for generating a sequence of voltage pulses based on DC signals is coupled between the first DC generator 32a and at least one lower electrode. Thus, the first DC generator 32a and the waveform generator form a voltage pulse generator. When the second DC generator 32b and the waveform generator form a voltage pulse generator, the voltage pulse generator is coupled to at least one upper electrode. The voltage pulses may have positive polarity or negative polarity. The sequence of voltage pulses may include one or more positive voltage pulses and one or more negative voltage pulses within one cycle. The power supply 30 may include the first DC generator 32a and the second DC generator 32b in addition to the RF power supply 31 or may include the first DC generator 32a in place of the second RF generator 31b.

The exhaust system 40 is connectable to, for example, a gas outlet 10e in the bottom of the plasma processing chamber 10. The exhaust system 40 may include a pressure control valve and a vacuum pump. The pressure control valve regulates the pressure in the plasma processing space 10s. The vacuum pump may be a turbomolecular pump, a dry pump, or a combination of these.

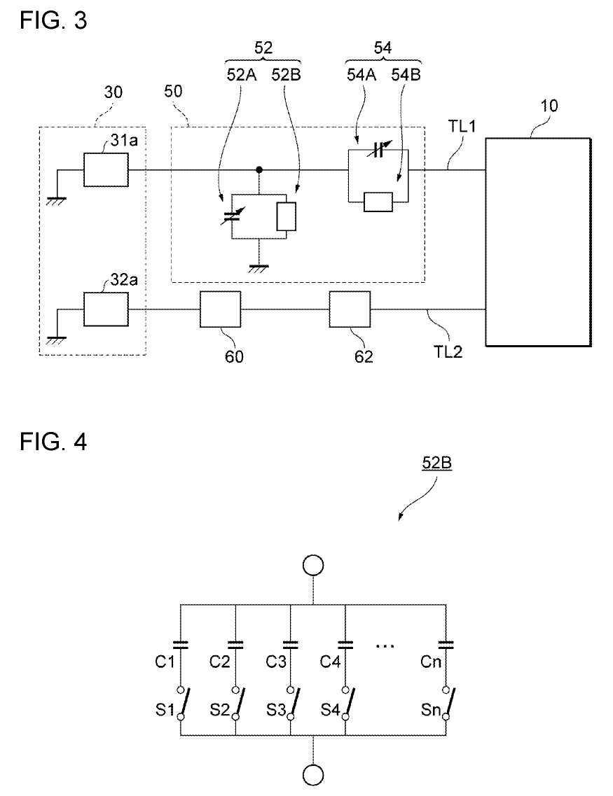

FIG. 3 is a diagram of an example of coupling between the power supply 30 and the plasma processing chamber 10 (hereafter also referred to as the chamber 10). In one embodiment, the first RF generator 31a is coupled to the chamber 10 with a first transmission line TL1. In one embodiment, the first RF generator 31a coupled to the chamber 10 includes the first RF generator 31a electrically coupled to the upper electrode or the lower electrode in the plasma processing apparatus 1. The first RF generator 31a generates a source RF signal for plasma generation and provides the source RF signal to the upper electrode or the lower electrode. In other words, the first RF generator 31a is an example of a source RF generator.

An impedance matcher 50 is located on the first transmission line TL1 between the first RF generator 31a and the chamber 10. The impedance matcher 50 is electrically coupled to the first transmission line TL1. In one embodiment, the impedance matcher 50 may include a first matching circuit 52 and a second matching circuit 54. The impedance matcher 50 controls variable capacitors in the first matching circuit 52 and the second matching circuit 54 to match the impedances of the first RF generator 31a and the chamber 10.

The first matching circuit 52 is located between the first transmission line TL1 and a ground potential. More specifically, the first matching circuit 52 has one end electrically coupled to the first transmission line TL1 and the other end electrically coupled to the ground potential as shown in FIG. 3. The first matching circuit 52 includes a first low-speed matching circuit 52A and a first high-speed matching circuit 52B. The first low-speed matching circuit 52A and the first high-speed matching circuit 52B each include a variable capacitor. As shown in FIG. 3, the first low-speed matching circuit 52A and the first high-speed matching circuit 52B are coupled in parallel with each other. More specifically, the first matching circuit 52 has a capacitance corresponding to the total capacitance of the first low-speed matching circuit 52A and the first high-speed matching circuit 52B.

The first low-speed matching circuit 52A has a capacitance adjustable to perform a low-speed matching operation on the source RF signal on the first transmission line TL1. In one embodiment, the low-speed matching operation may be performed repeatedly every about ten to several hundred milliseconds (ms).

In one embodiment, the first low-speed matching circuit 52A includes a mechanical variable capacitor. The mechanical variable capacitor may have a capacitance adjustable with driving of, for example, a motor or an actuator. The mechanical variable capacitor may be selected as appropriate to have a response performance (speed for switching from the maximum capacitance to the minimum capacitance) to be used for the low-speed matching operation. The mechanical variable capacitor may be, for example, a vacuum variable capacitor. In one embodiment, the first low-speed matching circuit 52A may include multiple mechanical variable capacitors. In one embodiment, the mechanical variable capacitor included in the first low-speed matching circuit 52A may have a maximum capacitance (the total maximum capacitance when the first low-speed matching circuit 52A includes multiple variable capacitors; the same applies hereafter) of about several ten to several thousand pF.

The first high-speed matching circuit 52B has a capacitance adjustable to perform a high-speed matching operation on the source RF signal on the first transmission line TL1. In one embodiment, the high-speed matching operation may be performed repeatedly every about several ten nanoseconds (ns) to several microseconds (μs). In one embodiment, the speed of the high-speed matching operation is set based on the frequency of the bias signal.

In one embodiment, the first high-speed matching circuit 52B includes an electronic variable capacitor. FIG. 4 is a diagram of an example electronic variable capacitor. As shown in FIG. 4, the electronic variable capacitor may include multiple capacitor elements (C1 to Cn) and multiple switching elements (S1 to Sn) electrically coupled to the respective capacitor elements. The electronic variable capacitor may have an overall capacitance adjustable by turning on or off each of the switching elements (S1 to Sn) in response to a control signal. In one embodiment, the switching elements (S1 to Sn) may be selected as appropriate to have a response performance (speed for switching between on and off) to be used for the high-speed matching operation. In one embodiment, the switching elements may be field-effect transistors (FETs).

In one embodiment, the electronic variable capacitor may be a board mount capacitor. In one embodiment, the first high-speed matching circuit 52B may include multiple electronic variable capacitors. The electronic variable capacitor included in the first high-speed matching circuit 52B may have a maximum capacitance (the total maximum capacitance when the first high-speed matching circuit 52B includes multiple variable capacitors; the same applies hereafter) of about ten to several hundred pF. In one embodiment, the mechanical variable capacitor included in the first low-speed matching circuit 52A may have a maximum capacitance greater than or equal to ten times the maximum capacitance of the electronic variable capacitor included in the first high-speed matching circuit 52B.

Referring back to FIG. 3, the second matching circuit 54 is located on the first transmission line TL1. More specifically, the second matching circuit 54 has one end electrically coupled to the first transmission line TL1 connecting to the first RF generator 31a and the other end electrically coupled to the first transmission line TL1 connecting to the chamber 10. The second matching circuit 54 includes a second low-speed matching circuit 54A and a second high-speed matching circuit 54B. The second low-speed matching circuit 54A and the second high-speed matching circuit 54B each include a variable capacitor. As shown in FIG. 3, the second low-speed matching circuit 54A and the second high-speed matching circuit 54B are coupled in parallel with each other. More specifically, the second matching circuit 54 has a capacitance corresponding to the total capacitance of the second low-speed matching circuit 54A and the second high-speed matching circuit 54B. In one embodiment, the second low-speed matching circuit 54A may have the same structure as the first low-speed matching circuit 52A describe above. The second high-speed matching circuit 54B may have the same structure as the first high-speed matching circuit 52B describe above.

In one embodiment, the first DC generator 32a is coupled to the chamber 10 with a second transmission line TL2. In one embodiment, the first DC generator 32a coupled to the chamber 10 includes the first DC generator 32a electrically coupled to the lower electrode in the plasma processing apparatus 1. The first DC generator 32a generates a first DC signal and provides the first DC signal to the lower electrode as a bias DC signal. In other words, the first DC generator 32a is an example of a bias generator.

In one embodiment, a waveform generator 60 may be located on the second transmission line TL2. The waveform generator 60 may generate a sequence of voltage pulses based on the first DC signal generated by the first DC generator 32a. In other words, the sequence of voltage pulses may be applied to the lower electrode. The voltage pulses may have rectangular, trapezoidal, or triangular pulse waveforms, or a combination of these. In one embodiment, the waveform generator 60 may be integral with the first DC generator 32a as a part of the power supply 30.

In one embodiment, an RF filter 62 may be located on the second transmission line TL2. The RF filter 62 reduces the likelihood of the RF signal, such as the source RF signal or the bias RF signal, entering the first DC generator 32a through the second transmission line TL2. The RF filter 62 may remove a signal with a specific frequency corresponding to the frequency of the RF signal. In one embodiment, the RF filter 62 may be a coil. In one embodiment, the RF filter 62 may be eliminated.

In one embodiment, each component shown in FIG. 3 may be controlled by the controller 2 (refer to FIG. 2). For example, the controller 2 may cause the first matching circuit 52 and the second matching circuit 54 to perform an impedance matching operation described below at the start of plasma generation (hereafter also referred to as ignition).

The functionality of the controller 2 may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry is hardware that carries out or is programmed to perform the recited functionality. The hardware may be any hardware disclosed herein which is programmed or configured to carry out the recited functionality.

### Example of Impedance Matching Method

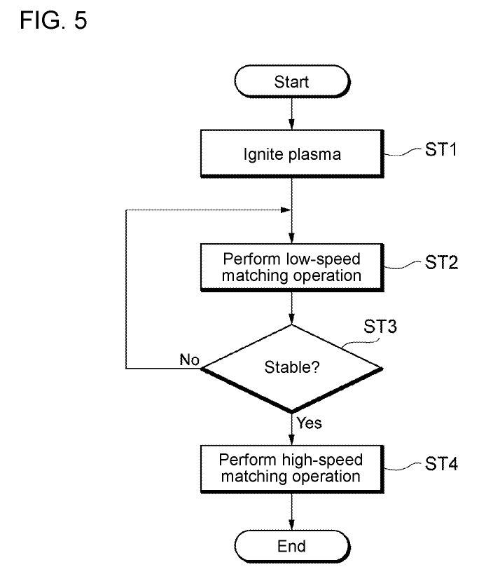

FIG. 5 is a flowchart of an example impedance matching method (hereafter also referred to as a matching method) according to one embodiment. As shown in FIG. 5, the matching method may include step ST1 of igniting a plasma, step ST2 of performing the low-speed matching operation, step ST3 of determining whether the low-speed matching operation is stable, and step ST4 of performing the high-speed matching operation.

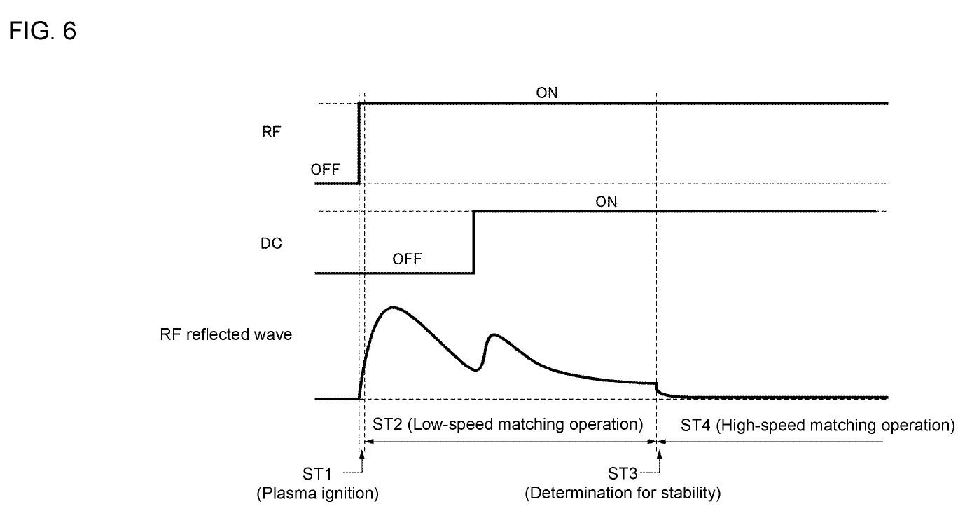

FIG. 6 is an example timing chart for the matching method. In FIG. 6, the horizontal axis is a time axis including steps ST1 to ST4 in the matching method. In one embodiment, the scale of the time axis (the time from the left to the right) in FIG. 6 may be about one second to several thousand seconds. In FIG. 6, the term RF indicates whether the source RF signal is provided (ON or OFF). The term DC indicates whether the bias DC signal is provided (ON or OFF). The term RF reflected wave indicates the power level of the reflected wave of the source RF signal propagating through the first transmission line TL1.

In step ST1, a plasma is ignited in the chamber 10. In one embodiment, the gas supply 20 supplies a gas for plasma generation to the plasma processing space 10s through the showerhead 13. The first RF generator 31a provides a source RF signal (The RF in FIG. 6 is changed from OFF to ON). This starts plasma generation in the chamber 10. In other words, the plasma is ignited. In one embodiment, the controller 2 may determine whether the plasma is ignited in the chamber 10. When determining that the plasma is ignited, the controller 2 may start the low-speed matching operation in step ST2.

In step ST2, the low-speed matching operation is performed. Immediately after the plasma is ignited (the plasma generation starts) in the chamber 10, the plasma in the chamber 10 is unstable and shows large fluctuations. The controller 2 causes the impedance matcher 50 to perform the low-speed matching operation on the source RF signal on the first transmission line TL1. The low-speed matching operation may be performed to cause the impedance of the first RF generator 31a to follow a relatively large load variation (impedance variation) of the chamber 10 during, for example, plasma ignition. In one embodiment, the low-speed matching operation may be performed repeatedly every ten to several hundred ms. In one embodiment, step ST2 may be performed for about 0.1 to several seconds. The duration of step ST2 is an example of a first period.

In one embodiment, the controller 2 changes the capacitances of the first low-speed matching circuit 52A and the second low-speed matching circuit 54A based on the RF reflection characteristics of the source RF signal propagating through the first transmission line TL1. The RF reflection characteristics may include one or more of, for example, (a) the ratio of power (Pf) of a traveling wave to power (Pr) of the reflected wave of the source RF signal, (b) a resistance component of an impedance, (c) a reflection coefficient, (d) a return loss, and (e) an S-parameter at the input end or the output end of the impedance matcher 50.

In one embodiment, the controller 2 may change the capacitance of the first low-speed matching circuit 52A and the capacitance of the second low-speed matching circuit 54A independently of each other. For example, the controller 2 may control the drive level of the motor in the mechanical variable capacitor included in the first low-speed matching circuit 52A to change the capacitance of the first low-speed matching circuit 52A independently of the second low-speed matching circuit 54A. For example, the controller 2 may control the drive level of the motor in the mechanical variable capacitor included in the second low-speed matching circuit 54A to change the capacitance of the second low-speed matching circuit 54A independently of the first low-speed matching circuit 52A.

In one embodiment, neither the capacitance of the first high-speed matching circuit 52B nor the capacitance of the second high-speed matching circuit 54B may be changed during the low-speed matching operation in step ST2. For example, the capacitances of the first high-speed matching circuit 52B and the second high-speed matching circuit 54B may each be maintained at a constant value (e.g., an intermediate value between the maximum capacitance and the minimum capacitance). In one embodiment, the capacitance of the first high-speed matching circuit 52B is maintained at a fixed value between the maximum capacitance and the minimum capacitance of the first high-speed matching circuit 52B, and the capacitance of the second high-speed matching circuit 54B is maintained at a fixed value between the maximum capacitance and the minimum capacitance of the second high-speed matching circuit 54B during the low-speed matching operation. In one embodiment, the capacitance of the first high-speed matching circuit 52B is maintained at a fixed value close to the intermediate value between the maximum capacitance and the minimum capacitance of the first high-speed matching circuit 52B, and the capacitance of the second high-speed matching circuit 54B is maintained at a fixed value close to the intermediate value between the maximum capacitance and the minimum capacitance of the second high-speed matching circuit 54B during the low-speed matching operation.

In one embodiment, the first DC generator 32a may provide a bias DC signal to the lower electrode through the second transmission line TL2 in step ST2 (The DC in FIG. 6 is switched from OFF to ON). The bias DC signal may be negative. The bias DC signal may be pulsed by the waveform generator 60 and include a sequence of voltage pulses (hereafter also referred to as a pulsed DC signal). The pulsed DC signal has a lower frequency than the source RF signal. In one embodiment, the pulsed DC signal has a frequency in a range of 100 kHz to 1 MHz. The bias DC signal may be positive to provide a potential difference between the plasma in the chamber 10 and the lower electrode (or a substrate on the lower electrode). In one embodiment, the bias DC signal may be provided at the start of step ST2 or when the plasma is ignited before the start of step ST2.

As shown in FIG. 6, the low-speed matching operation in step ST2 gradually reduces the power level of the reflected wave of the source RF signal. In other words, the impedance of the first RF generator 31a follows the load variation of the plasma (impedance variation of the chamber 10) resulting from the plasma ignition, thus stabilizing the low-speed matching operation.

In step ST3, the controller 2 determines whether the low-speed matching operation is stable. When the low-speed matching operation is determined to be stable, the low-speed matching operation ends, and the high-speed matching operation in step ST4 is performed. When the low-speed matching operation is not determined to be stable, the low-speed matching operation continues. The determination may be performed based on, for example, whether the reflected wave of the source RF signal has a power level less than or equal to a given threshold. For example, the determination may be performed based on, for example, the duration of the low-speed matching operation, the variation in the flow rate of a gas supplied to the chamber 10, or whether the source RF signal is output at a set power level.

In step ST4, the high-speed matching operation is performed. The controller 2 causes the impedance matcher 50 to perform the high-speed matching operation on the source RF signal on the first transmission line TL1. The high-speed matching operation may be performed to cause the impedance of the first RF generator 31a to follow a high-speed load variation (impedance variation) of the chamber 10 while, for example, the bias signal is being provided. In one embodiment, the high-speed matching operation may be performed repeatedly every about several ten ns to several μs. In one embodiment, the high-speed matching operation may be performed after the low-speed matching operation. In one embodiment, step ST4 may be performed for about several seconds to several ten minutes. The duration of step ST4 is an example of a second period.

In one embodiment, the controller 2 changes the capacitances of the first high-speed matching circuit 52B and the second high-speed matching circuit 54B based on the RF reflection characteristics of the source RF signal propagating through the first transmission line TL1. The RF reflection characteristics may include one or more of, for example, (a) the ratio of power (Pf) of a traveling wave to power (Pr) of a reflected wave of the source RF signal, (b) a resistance component of an impedance, (c) a reflection coefficient, (d) a return loss, and (e) an S-parameter at the input end or the output end of the impedance matcher 50. In one embodiment, the controller 2 changes the capacitances of the first high-speed matching circuit 52B and the second high-speed matching circuit 54B based on a synchronization signal. A synchronization signal generator for generating a synchronization signal may be included in the first RF generator 31a or the second RF generator 31b, or may be external to the first RF generator 31a and the second RF generator 31b.

In one embodiment, the controller 2 may change the capacitance of the first high-speed matching circuit 52B and the capacitance of the second high-speed matching circuit 54B independently of each other. For example, the controller 2 may control the on-off state of each switching element in the electronic variable capacitor included in the first high-speed matching circuit 52B to change the capacitance of the first high-speed matching circuit 52B independently of the capacitance of the second high-speed matching circuit 54B. For example, the controller 2 may control the on-off state of each switching element in the electronic variable capacitor included in the second high-speed matching circuit 54B to change the capacitance of the second high-speed matching circuit 54B independently of the capacitance of the first high-speed matching circuit 52B.

In one embodiment, neither the capacitance of the first low-speed matching circuit 52A nor the capacitance of the second low-speed matching circuit 54A may be changed during the high-speed matching operation in step ST4. For example, each capacitance of the first low-speed matching circuit 52A and the second low-speed matching circuit 54A may be maintained at a value at the end of step ST2 (matching stability point). When the plasma is switched during the high-speed matching in step ST4 by switching, for example, the processing gas or an RF condition, the high-speed matching operation is to be switched to the low-speed matching operation to perform a stabilizing procedure again. In this case, the processing returns from the high-speed matching operation in step ST4 to the low-speed matching operation in step ST2 to perform the procedure in FIG. 5 again.

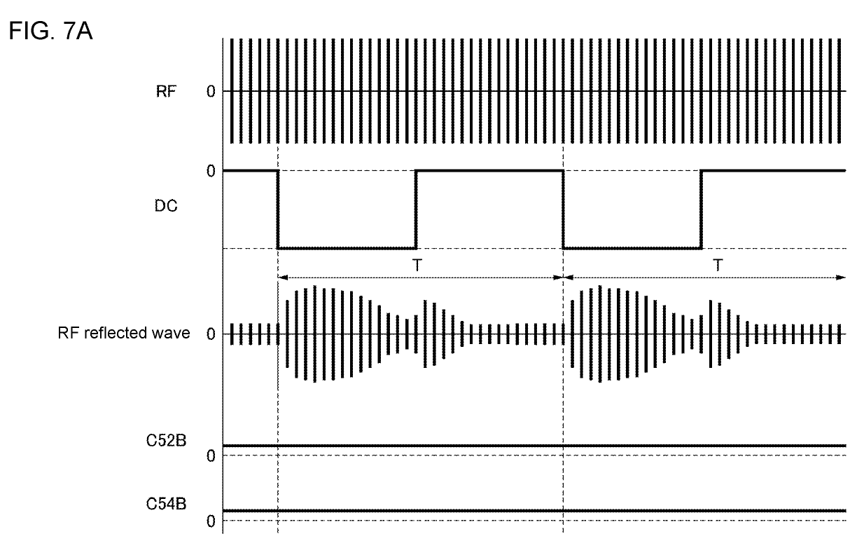

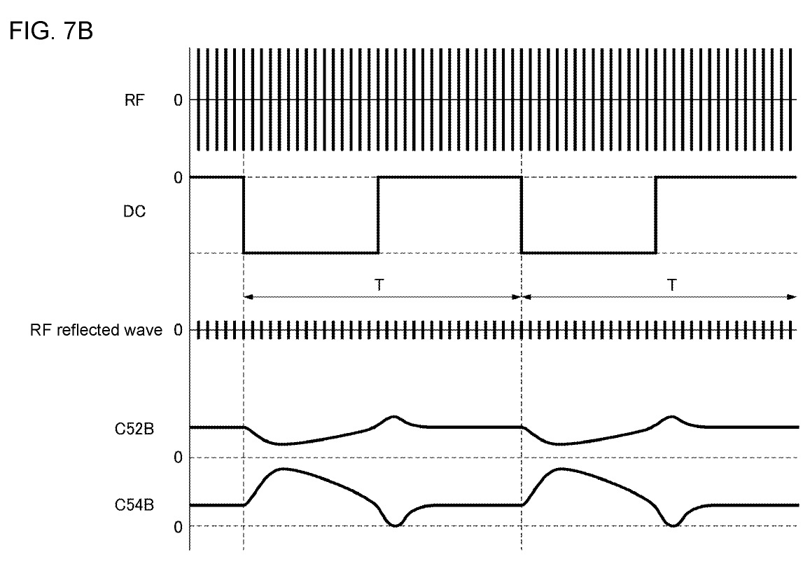

FIG. 7A is an example timing chart with the high-speed matching operation not performed. FIG. 7B is an example timing chart with the high-speed matching operation performed. In FIGS. 7A and 7B, the horizontal axis is a time axis corresponding to a cycle T of the pulsed DC signal. In one embodiment, the scale of the time axis (the time from the left end to the right end) in FIGS. 7A and 7B may be 200 ns to 1 μs. In FIGS. 7A and 7B, RF indicates the power level of the source RF signal. DC indicates the voltage level of the pulsed DC signal. RF reflected wave indicates the power level of the reflected wave of the source RF signal propagating through the first transmission line TL1. C52B is the capacitance of the first high-speed matching circuit 52B. C54B is the capacitance of the second high-speed matching circuit 54B.

In the example in FIG. 7A, the high-speed matching operation is not performed, or more specifically, step ST4 is not performed and the capacitances of the first high-speed matching circuit 52B and the second high-speed matching circuit 54B are maintained constantly. In this case, the power level of the reflected wave increases in synchronization with the voltage level of the pulsed DC signal. When the high-speed matching operation is not performed, the load variation of the plasma resulting from the pulsed DC signal may cause intermodulation distortion (IMD). IMD causes a mismatch with the fundamental wave of the source RF signal resulting from the frequency modulation to increase the power level of the reflected wave of the source RF signal.

In the example in FIG. 7B, the high-speed matching operation is performed, or more specifically, step ST4 is performed to follow the load variation resulting from the pulsed DC signal and change the capacitances of the first high-speed matching circuit 52B and the second high-speed matching circuit 54B at a high speed. In this case, the power level of the reflected wave is lower than in the example shown in FIG. 7A. The high-speed matching operation reduces the load variation resulting from the pulsed DC signal and thus reduces IMD. In other words, the matching method can reduce IMD.

The impedance varies two-dimensionally within the load range in response to a load variation. Thus, the matching operation has higher accuracy when including two or more impedance adjusters (knobs). The matching method allows the capacitance of the first high-speed matching circuit 52B and the capacitance of the second high-speed matching circuit 54B to be changed independently of each other in the high-speed matching operation in step ST4. In other words, the high-speed matching operation in step ST4 includes two impedance adjusters (knobs) and thus has high accuracy. This structure further reduces IMD.

The matching method selectively uses the mechanical variable capacitor and the electronic variable capacitor based on the load variation range and the speed. More specifically, the low-speed matching operation in step ST2 is performed using the first low-speed matching circuit 52A and the second low-speed matching circuit 54A. The load variation immediately after plasma ignition has a wider range than the load variation resulting from the pulsed DC signal, but is at a lower speed. Thus, the first low-speed matching circuit 52A and the second low-speed matching circuit 54A each including the mechanical variable capacitor may be used. In contrast, the high-speed matching operation in step ST4 is performed using the first high-speed matching circuit 52B and the second high-speed matching circuit 54B. The load variation resulting from the pulsed DC signal is at a higher speed than the load variation immediately after the plasma ignition, but has a narrower range. Thus, the first high-speed matching circuit 52B and the second high-speed matching circuit 54B each including the electronic variable capacitor may be used.

### Modifications

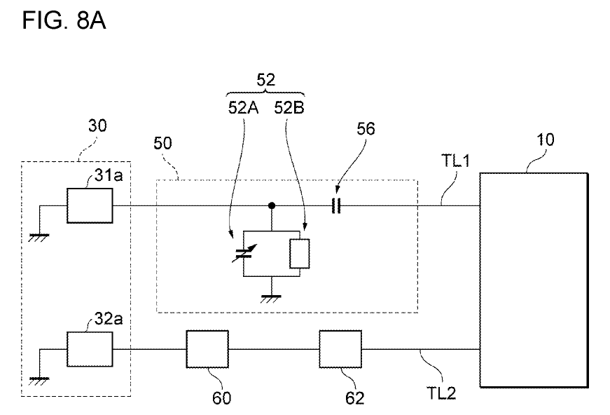

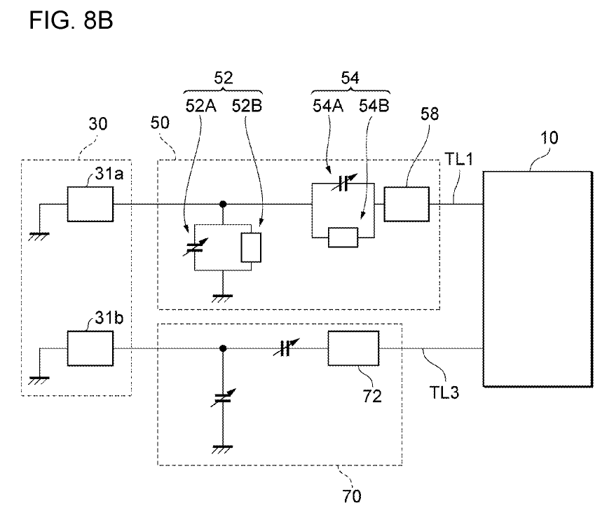

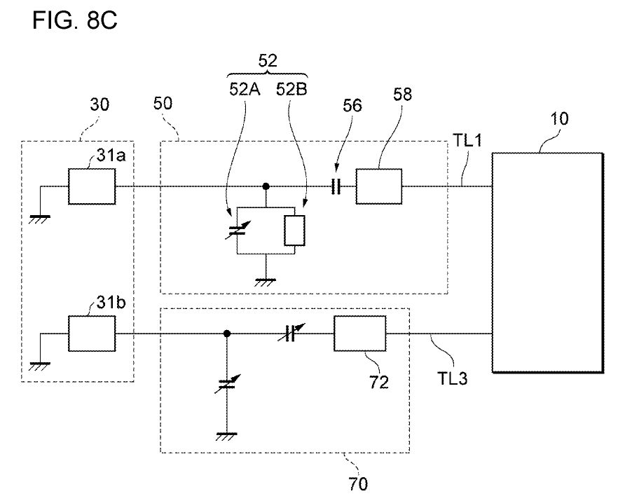

FIGS. 8A to 8C are diagrams of examples of coupling in modifications of the structure shown in FIG. 3. The modifications will be described focusing on the differences from the structure shown in FIG. 3. The same structure will not be described.

In one embodiment, the impedance matcher 50 may not include the second matching circuit 54. For example, the impedance matcher 50 may include a capacitor 56 in place of the second matching circuit 54 as shown in FIGS. 8A and 8C. The capacitor 56 may be located on the first transmission line TL1. The capacitor 56 may be, for example, a vacuum capacitor. The capacitor 56 may be a mechanical variable capacitor (e.g., a vacuum variable capacitor).

In the examples shown in FIGS. 8A and 8C, the first RF generator 31a may change the frequency of the RF signal to be provided. For example, the first RF generator 31a may have a frequency changeable between a minimum frequency (e.g., −10% of a designed frequency) and a maximum frequency (e.g., +10% of a designed frequency). In the high-speed matching operation in step ST4, the controller 2 may change the capacitance of the first high-speed matching circuit 52B and the frequency of the RF signal provided from the first RF generator 31a to follow the load variation resulting from the bias signal (pulsed DC signal or bias RF signal). In this case, the first RF generator 31a functions as, together with the first high-speed matching circuit 52B, an impedance adjuster (knob) in the high-speed matching operation in step ST4.

In one embodiment, a bias RF signal generated from the second RF generator 31b may be provided to the lower electrode in the chamber 10, instead of or in addition to the first DC signal to the lower electrode as a bias signal. As shown in, for example, FIGS. 8B and 8C, the second RF generator 31b may be electrically coupled to the lower electrode in the chamber 10 through a third transmission line TL3. An impedance matcher 70 is located on the third transmission line TL3. As shown in FIGS. 8B and 8C, the impedance matcher 50 for the source RF signal may include an RF filter 58. The RF filter 58 reduces the likelihood of the bias RF signal entering the first RF generator 31a through the first transmission line TL1. The impedance matcher 70 for the bias RF signal may include an RF filter 72. The RF filter 72 reduces the likelihood of the bias RF signal entering the second RF generator 31b through the third transmission line TL3. In the example shown in FIG. 8B, the controller 2 may change the capacitances of the first high-speed matching circuit 52B and the second high-speed matching circuit 54B to follow the load variation resulting from the bias RF signal in the high-speed matching operation in step ST4.

The technique according to one or more embodiments of the present disclosure may be implemented with, other than the capacitively coupled plasma processing apparatus, the plasma processing apparatus 1 using any plasma source. For example, the matching operation may be performed by an inductively coupled plasma processing apparatus. In this case, the inductively coupled plasma processing apparatus is located in a chamber and includes a substrate support including a lower electrode and an antenna located above the chamber. The inductively coupled plasma processing apparatus may have the same structure as the structure described with reference to FIGS. 3 and 8A to 8C. The first RF generator 31a may be coupled to the antenna with the first transmission line TL1. The impedance matcher 50 described above may be located on the first transmission line TL1.

The embodiments of the present disclosure further include the aspects described below.

### Appendix 1

A plasma processing apparatus, comprising:

a chamber;

a substrate support located in the chamber and including a lower electrode;

an upper electrode located above the substrate support;

a source radio-frequency generator configured to provide a source radio-frequency signal to the upper electrode or the lower electrode to generate a plasma in the chamber;

an impedance matcher electrically coupled to a transmission line between the source radio-frequency generator and the upper electrode or between the source radio-frequency generator and the lower electrode, the impedance matcher including a first low-speed matching circuit and a first high-speed matching circuit coupled in parallel with each other;

a bias generator configured to provide a bias signal to the lower electrode; and

a controller configured to cause the first low-speed matching circuit to perform a low-speed matching operation on the source radio-frequency signal in a first period and to cause the first high-speed matching circuit to perform a high-speed matching operation on the source radio-frequency signal in a second period following the first period.

### Appendix 2

The plasma processing apparatus according to appendix 1, wherein

the first low-speed matching circuit includes a first mechanical variable capacitor,

the first high-speed matching circuit includes a first electronic variable capacitor, and

the first electronic variable capacitor includes a plurality of first capacitor elements and a plurality of first switching elements electronically coupled to the plurality of respective first capacitor elements.

### Appendix 3

The plasma processing apparatus according to appendix 2, wherein

the first mechanical variable capacitor has a maximum capacitance greater than or equal to ten times a maximum capacitance of the first electronic variable capacitor.

### Appendix 4

The plasma processing apparatus according to any one of appendixes 1 to 3, wherein

the first low-speed matching circuit performs the low-speed matching operation every about ten to several hundred milliseconds, and the first high-speed matching circuit performs the high-speed matching operation every about several ten nanoseconds to several microseconds.

### Appendix 5

The plasma processing apparatus according to any one of appendixes 1 to 4, wherein

the first period is a period from when plasma generation is started in the chamber to when the low-speed matching operation stabilizes.

### Appendix 6

The plasma processing apparatus according to any one of appendixes 1 to 5, wherein

the first low-speed matching circuit and the first high-speed matching circuit are located between the transmission line and a ground potential.

### Appendix 7

The plasma processing apparatus according to any one of appendixes 1 to 6, wherein

the impedance matcher includes a second low-speed matching circuit and a second high-speed matching circuit coupled in parallel with each other, and the second low-speed matching circuit and the second high-speed matching circuit are located on the transmission line.

### Appendix 8

The plasma processing apparatus according to appendix 7, wherein

the first low-speed matching circuit includes a first mechanical variable capacitor,

the first high-speed matching circuit includes a first electronic variable capacitor,

the first electronic variable capacitor includes a plurality of first capacitor elements and a plurality of first switching elements electronically coupled to the plurality of respective first capacitor elements,

the second low-speed matching circuit includes a second mechanical variable capacitor,

the second high-speed matching circuit includes a second electronic variable capacitor, and

the second electronic variable capacitor includes a plurality of second capacitor elements and a plurality of second switching elements electronically coupled to the plurality of respective second capacitor elements.

### Appendix 9

The plasma processing apparatus according to appendix 6, wherein

the source radio-frequency generator changes a set value of a frequency of the source radio-frequency signal.

### Appendix 10

The plasma processing apparatus according to any one of appendixes 1 to 9, wherein

the bias generator includes a bias radio-frequency generator configured to generate a bias radio-frequency signal.

### Appendix 11

The plasma processing apparatus according to any one of appendixes 1 to 10, wherein

the bias generator includes a bias direct current generator configured to generate a bias direct current signal, and the bias direct current signal has a sequence of voltage pulses.

### Appendix 12

A plasma processing apparatus, comprising:

a chamber;

a substrate support located in the chamber and including a lower electrode;

an antenna located above the chamber;

a source radio-frequency generator configured to provide a source radio-frequency signal to the antenna to generate a plasma in the chamber;

an impedance matcher electrically coupled to a transmission line between the source radio-frequency generator and the antenna, the impedance matcher including a first low-speed matching circuit and a first high-speed matching circuit coupled in parallel with each other;

a bias generator configured to provide a bias signal to the lower electrode; and

a controller configured to cause the first low-speed matching circuit to perform a low-speed matching operation on the source radio-frequency signal in a first period and to cause the first high-speed matching circuit to perform a high-speed matching operation on the source radio-frequency signal in a second period following the first period.

### Appendix 13

The plasma processing apparatus according to appendix 12, wherein

the first low-speed matching circuit includes a first mechanical variable capacitor,

the first high-speed matching circuit includes a first electronic variable capacitor, and

the first electronic variable capacitor includes a plurality of first capacitor elements and a plurality of first switching elements electronically coupled to the plurality of respective first capacitor elements.

### Appendix 14

The plasma processing apparatus according to appendix 12 or appendix 13, wherein

the first low-speed matching circuit and the first high-speed matching circuit are located between the transmission line and a ground potential.

### Appendix 15

The plasma processing apparatus according to any one of appendixes 12 to 14, wherein

the impedance matcher includes a second low-speed matching circuit and a second high-speed matching circuit coupled in parallel with each other, and the second low-speed matching circuit and the second high-speed matching circuit are located on the transmission line.

### Appendix 16

The plasma processing apparatus according to appendix 15, wherein

the first low-speed matching circuit includes a first mechanical variable capacitor,

the first high-speed matching circuit includes a first electronic variable capacitor,

the first electronic variable capacitor includes a plurality of first capacitor elements and a plurality of first switching elements electronically coupled to the plurality of respective first capacitor elements,

the second low-speed matching circuit includes a second mechanical variable capacitor,

the second high-speed matching circuit includes a second electronic variable capacitor, and

the second electronic variable capacitor includes a plurality of second capacitor elements and a plurality of second switching elements electronically coupled to the plurality of respective second capacitor elements.

### Appendix 17

The plasma processing apparatus according to any one of appendixes 14 to 16, wherein

the source radio-frequency generator changes a frequency of the source radio-frequency signal.

### Appendix 18

An impedance matching method, comprising:

providing a radio-frequency signal to a load from a radio-frequency generator;

causing a first low-speed matching circuit to perform a low-speed matching operation on the radio-frequency signal in a first period; and

causing a first high-speed matching circuit to perform a high-speed matching operation on the radio-frequency signal in a second period following the first period, the first high-speed matching circuit being coupled in parallel with the first low-speed matching circuit.

### Appendix 19

The impedance matching method according to appendix 18, wherein

the first low-speed matching circuit includes a first mechanical variable capacitor,

the first high-speed matching circuit includes a first electronic variable capacitor, and

the first electronic variable capacitor includes a plurality of first capacitor elements and a plurality of first switching elements electronically coupled to the plurality of respective first capacitor elements.

The above embodiments are mere examples described for illustrative purposes and are not intended to limit the scope of the present disclosure. The embodiments may be modified in various manners without departing from the spirit and scope of the present disclosure. For example, one or more components in one embodiment may be added to the structure according to another embodiment. One or more components in one embodiment may be replaced with the corresponding one or more components in another embodiment.

The technique according to one exemplary embodiment of the present disclosure reduces intermodulation distortion.

What is claimed is:

1. A plasma processing apparatus, comprising:
a chamber;
a substrate support located in the chamber and including a lower electrode;
an upper electrode located above the substrate support;
a source radio-frequency generator configured to provide a source radio-frequency signal to the upper electrode or the lower electrode to generate a plasma in the chamber;
an impedance matcher electrically coupled to a transmission line between the source radio-frequency generator and the upper electrode or between the source radio-frequency generator and the lower electrode, the impedance matcher including a first low-speed matching circuit and a first high-speed matching circuit coupled in parallel with each other;
a bias generator configured to provide a bias signal to the lower electrode; and
a controller configured to cause the first low-speed matching circuit to perform a low-speed matching operation on the source radio-frequency signal in a first period and to cause the first high-speed matching circuit to perform a high-speed matching operation on the source radio-frequency signal in a second period following the first period.

2. The plasma processing apparatus according to claim 1, wherein
the first low-speed matching circuit includes a first mechanical variable capacitor,
the first high-speed matching circuit includes a first electronic variable capacitor, and
the first electronic variable capacitor includes a plurality of first capacitor elements and a plurality of first switching elements electronically coupled to the plurality of respective first capacitor elements.

3. The plasma processing apparatus according to claim 2, wherein
the first mechanical variable capacitor has a maximum capacitance greater than or equal to ten times a maximum capacitance of the first electronic variable capacitor.

4. The plasma processing apparatus according to claim 3, wherein
the first low-speed matching circuit performs the low-speed matching operation every ten to several hundred milliseconds, and the first high-speed matching circuit performs the high-speed matching operation every about several ten nanoseconds to several microseconds.

5. The plasma processing apparatus according to claim 1, wherein
the first period is a period from when plasma generation is started in the chamber to when the low-speed matching operation stabilizes.

6. The plasma processing apparatus according to claim 1, wherein
the first low-speed matching circuit and the first high-speed matching circuit are located between the transmission line and a ground potential.

7. The plasma processing apparatus according to claim 6, wherein
the impedance matcher includes a second low-speed matching circuit and a second high-speed matching circuit coupled in parallel with each other, and the second low-speed matching circuit and the second high-speed matching circuit are located on the transmission line.

8. The plasma processing apparatus according to claim 7, wherein
the first low-speed matching circuit includes a first mechanical variable capacitor,
the first high-speed matching circuit includes a first electronic variable capacitor,
the first electronic variable capacitor includes a plurality of first capacitor elements and a plurality of first switching elements electronically coupled to the plurality of respective first capacitor elements,
the second low-speed matching circuit includes a second mechanical variable capacitor,
the second high-speed matching circuit includes a second electronic variable capacitor, and
the second electronic variable capacitor includes a plurality of second capacitor elements and a plurality of second switching elements electronically coupled to the plurality of respective second capacitor elements.

9. The plasma processing apparatus according to claim 6, wherein
the source radio-frequency generator changes a set value of a frequency of the source radio-frequency signal.

10. The plasma processing apparatus according to claim 1, wherein
the bias generator includes a bias radio-frequency generator configured to generate a bias radio-frequency signal.

11. The plasma processing apparatus according to claim 1, wherein
the bias generator includes a bias direct current generator configured to generate a bias direct current signal, and the bias direct current signal has a sequence of voltage pulses.

12. A plasma processing apparatus, comprising:
a chamber;
a substrate support located in the chamber and including a lower electrode;
an antenna located above the chamber;
a source radio-frequency generator configured to provide a source radio-frequency signal to the antenna to generate a plasma in the chamber;
an impedance matcher electrically coupled to a transmission line between the source radio-frequency generator and the antenna, the impedance matcher including a first low-speed matching circuit and a first high-speed matching circuit coupled in parallel with each other;
a bias generator configured to provide a bias signal to the lower electrode; and
a controller configured to cause the first low-speed matching circuit to perform a low-speed matching operation on the source radio-frequency signal in a first period and to cause the first high-speed matching circuit to perform a high-speed matching operation on the source radio-frequency signal in a second period following the first period.

13. The plasma processing apparatus according to claim 12, wherein
the first low-speed matching circuit includes a first mechanical variable capacitor,
the first high-speed matching circuit includes a first electronic variable capacitor, and
the first electronic variable capacitor includes a plurality of first capacitor elements and a plurality of first switching elements electronically coupled to the plurality of respective first capacitor elements.

14. The plasma processing apparatus according to claim 12, wherein
the first low-speed matching circuit and the first high-speed matching circuit are located between the transmission line and a ground potential.

15. The plasma processing apparatus according to claim 14, wherein
the impedance matcher includes a second low-speed matching circuit and a second high-speed matching circuit coupled in parallel with each other, and the second low-speed matching circuit and the second high-speed matching circuit are located on the transmission line.

16. The plasma processing apparatus according to claim 15, wherein
the first low-speed matching circuit includes a first mechanical variable capacitor,
the first high-speed matching circuit includes a first electronic variable capacitor,
the first electronic variable capacitor includes a plurality of first capacitor elements and a plurality of first switching elements electronically coupled to the plurality of respective first capacitor elements,
the second low-speed matching circuit includes a second mechanical variable capacitor,
the second high-speed matching circuit includes a second electronic variable capacitor, and
the second electronic variable capacitor includes a plurality of second capacitor elements and a plurality of second switching elements electronically coupled to the plurality of respective second capacitor elements.

17. The plasma processing apparatus according to claim 14, wherein
the source radio-frequency generator changes a frequency of the source radio-frequency signal.

18. An impedance matching method, comprising:
providing a radio-frequency signal to a load from a radio-frequency generator;
causing a first low-speed matching circuit to perform a low-speed matching operation on the radio-frequency signal in a first period; and
causing a first high-speed matching circuit to perform a high-speed matching operation on the radio-frequency signal in a second period following the first period, the first high-speed matching circuit being coupled in parallel with the first low-speed matching circuit.

19. The impedance matching method according to claim 18, wherein
the first low-speed matching circuit includes a first mechanical variable capacitor,
the first high-speed matching circuit includes a first electronic variable capacitor, and
the first electronic variable capacitor includes a plurality of first capacitor elements and a plurality of first switching elements electronically coupled to the plurality of respective first capacitor elements.
